(19) United States
(12) Patent Application Publication
(10) Pub. No.: US 2024/0170510 A1
(43) Pub. Date: May 23, 2024

(54) IMAGE SENSOR MODULE

(71) Applicant: SAMSUNG ELECTRONICS CO., LTD., Suwon-si (KR)

(72) Inventors: In-Sang SONG, Suwon-si (KR); Kyungsung CHU, Suwon-si (KR)

(21) Appl. No.: 18/220,394

(22) Filed: Jul. 11, 2023

(30) Foreign Application Priority Data
Nov. 22, 2022 (KR) 10-2022-0157221

(51) Int. Cl. H01L 27/146

(52) U.S. Cl. CPC H01L 27/14618; H01L 27/14627; H01L 27/14636; H01L 27/14683

(57) ABSTRACT

An image sensor module having an image sensor chip configured to convert light collected from an outside into an electric signal, a substrate on which the image sensor chip is installed, a bonding wire electrically connecting the image sensor chip and the substrate, an encapsulant for encapsulating the bonding wire by surrounding the side part of the image sensor chip, and a housing having a lower part spaced apart from the encapsulant and bonded on the substrate, and an upper part having an opening through which an external light is incident to the image sensor chip and supported by the encapsulant.

### CROSS-REFERENCE TO RELATED APPLICATION

Korean Patent Application No. 10-2022-0157221, filed on Nov. 22, 2022, in the Korean Intellectual Property Office, is incorporated herein by reference in its entirety.

### BACKGROUND

### 1. Field

The present disclosure relates to an image sensor module.

### 2. Description of the Related Art

An image sensor is a semiconductor-based sensor that receives light and generates an electric signal, and is widely applied to digital cameras, smartphones, automobiles, security devices, and robots.

### SUMMARY

Embodiments are directed to an image sensor module, including an image sensor chip configured to convert light collected from an outside into an electric signal, a substrate on which the image sensor chip is installed, a bonding wire electrically connecting the image sensor chip and the substrate, an encapsulant for encapsulating the bonding wire by surrounding the side part of the image sensor chip, and a housing having a lower part spaced apart from the encapsulant and bonded on the substrate, and an upper part having an opening through which an external light is incident to the image sensor chip and supported by the encapsulant.

Embodiments are directed to an image sensor module, including an image sensor chip that converts light collected from an outside into an electric signal, a substrate on which the image sensor chip is installed, a bonding wire connecting a chip pad on the upper surface edge of the image sensor chip and a substrate pad on the upper surface of the substrate, a housing coupled to the substrate, surrounding the image sensor chip, and having an opening through which an external light is incident to the image sensor chip, an optical filter positioned on the image sensor chip and spaced apart from the image sensor chip, and an encapsulant that encloses the side part of the image sensor chip to encapsulate the bonding wire, supports the upper portion of the housing while defining a separation space with the housing, and supports the optical filter.

Embodiments are directed to an image sensor module, including an image sensor chip that converts light collected from an outside into an electric signal, a substrate on which the image sensor chip is installed, a bonding wire electrically connecting the image sensor chip and the substrate, an encapsulant that encloses a side part of the image sensor chip and encapsulates the bonding wire while covering some regions of the upper surface of the substrate, an optical filter positioned on the image sensor chip spaced apart from the image sensor chip and supported on the encapsulant, a housing including an exterior wall that is bonded to the substrate, spaced apart from the encapsulant and that surrounds the encapsulant, and a cover that is spaced apart from the substrate, extends inward from the exterior wall, has an opening through which an external light is incident to the image sensor chip, and is supported to the upper surface of the encapsulant, and a lens holder having a plurality of lenses, combined on the cover, and having a width greater than or equal to that of the encapsulant.

### BRIEF DESCRIPTION OF THE DRAWINGS

Features will become apparent to those of skill in the art by describing in detail exemplary embodiments with reference to the attached drawings, in which:

FIG. 1 is an exploded, perspective view of an image sensor module according to an example embodiment;

FIG. 2 is a cross-sectional view of an image sensor module according to an example embodiment;

FIG. 3 is a cross-sectional view of a direction A-A of FIG. 2;

FIG. 4 is a cross-sectional view of a direction B-B of FIG. 2;

FIG. 5 is a view of a size relationship between components;

FIG. 6 is an enlarged view showing a part C of FIG. 2;

FIG. 7 is a view showing a modified form of a part C of FIG. 2;

FIG. 8 is an exploded, perspective view of an image sensor module according to an example embodiment;

FIG. 9 is a cross-sectional view of an image sensor module according to an example embodiment; and

FIG. 10 to FIG. 12 are views showing a manufacturing method of an image sensor module according to an example embodiment.

### DETAILED DESCRIPTION

Hereinafter, an embodiment will be described in detail with reference to the accompanying drawings so that a person having ordinary skill in the art can easily make it. As those of ordinary skill in the art would realize, the described embodiments may be modified in various different ways.

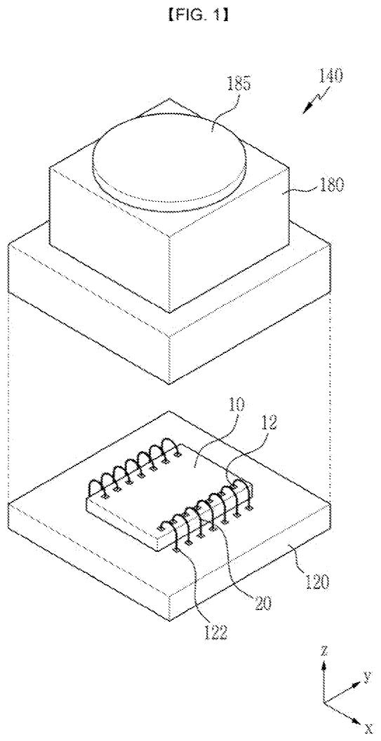

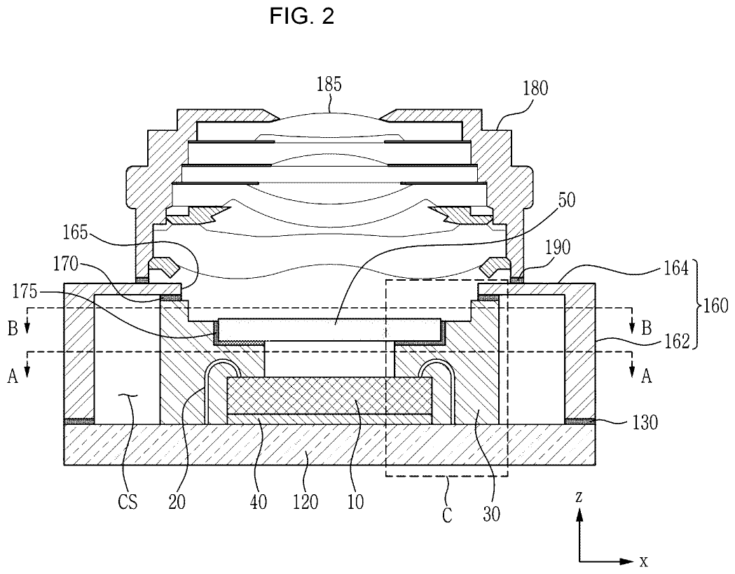

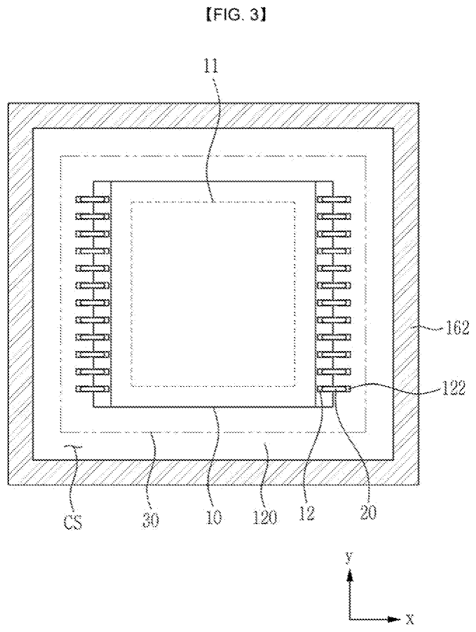

FIG. 1 is an exploded, perspective view of an image sensor module according to an example embodiment, FIG. 2 is a cross-sectional view of an image sensor module according to an example embodiment, and FIG. 3 is a cross-sectional view of a direction A-A of FIG. 2.

Referring to FIG. 1 to FIG. 3, an image sensor module 100 according to an example embodiment may include an image sensor chip 10, a substrate 120, a bonding wire 20, an encapsulant 30, and a housing 160. In addition, a lens holder 180 combined with the optical filter 50 and the housing 160 positioned above the image sensor chip 10 may be further included.

The image sensor chip 10 may be a semiconductor device that converts light collected from the outside into an electric signal, and may include a CMOS image sensor (CIS) and a charge-coupled device (CCD).

One surface (e.g., an upper surface) of the image sensor chip 10 may include a sensing region 11 and an outer region around the sensing region 11. The sensing region 11 may include a pixel array including a plurality of unit pixels. A plurality of unit pixels may be arranged in a two-dimensional array form. A plurality of unit pixels may be, e.g., a passive pixel sensor or an active pixel sensor. Each of a plurality of unit pixels may include a photodiode for sensing light, a transfer transistor for transferring charges generated by the photodiode, a floating diffusion region for storing the transferred charges, a reset transistor for periodically resetting the floating diffusion region, and a source follower for buffering a signal depending on the charges charged in the floating diffusion region.

In the sensing region 11, a plurality of color filters and a plurality of micro lenses may be sequentially disposed on a plurality of unit pixels. A plurality of color filters may include, e.g., a R (red) filter, a B (blue) filter or a G (green) filter. A plurality of color filters may include a C (cyan) filter, a Y (yellow) filter or an M (magenta) filter. On each of a plurality of unit pixels, a color filter may include the R filter, the B filter, the G filter, C filter, the Y filter or the M filter. A plurality of unit pixels may detect the components of each separated incident light to recognize one color. A plurality of micro lenses may focus light incident on the sensing region 11 to a plurality of unit pixels. As used herein, the term “or” is not an exclusive term, e.g., “A or B” would include A, B, or A and B.

The outer region of the image sensor chip 10 may be a region around the sensing region 11 and may be the edge region of the image sensor chip 10. A plurality of chip pads 12 may be in the outer region. The chip pad 12 may be electrically connected to a plurality of unit pixels in the sensing region 11. The chip pad 12 may include a metal such as copper (Cu), aluminum (Al), tungsten W, titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru).

The substrate 120 may be a part where the image sensor chip 10 is installed, and according to an example embodiment, the image sensor chip 10 may be disposed on the substrate 120. More specifically, the image sensor chip 10 may be attached to the upper surface of the substrate 120 through the first adhesive layer 40. The first adhesive layer 40 may include an adhesive material, e.g., a die attach film (DAF).

The substrate 120 may be a package substrate for packaging the image sensor chip 10, and may be, e.g., a printed circuit board, (PCB). The substrate 120 may include a plurality of insulation layers and a plurality of wiring layers.

The substrate 120 may include a plurality of substrate pads 122 disposed on the upper surface. The substrate pad 122 may be electrically connected to at least one of the plurality of aforementioned wiring layers. In an implementation, the substrate pad 122 may be electrically connected to the wiring layer through a conductive via penetrating the aforementioned insulation layer.

The substrate pad 122 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru).

The bonding wire 20 may be a conductive member that may electrically connect the image sensor chip 10 and the substrate 120. The bonding wire 20 may include a conductive metal such as gold (Au) or copper (Cu).

According to an example embodiment, the bonding wire 20 may connect between the chip pad 12 of the image sensor chip 10 and the substrate pad 122 of the substrate 120, thereby electrically connecting the chip pad 12 of the image sensor chip 10 and the substrate pad 122 of the substrate 120.

The housing 160 may be a portion for protecting the image sensor chip 10, and may be coupled onto the substrate 120 to have a shape surrounding the image sensor chip 10. The lower portion of the housing 160 may be coupled onto the substrate 120, and the upper portion of the housing 160 may have an opening 165 through which an external light is incident to the image sensor chip 10.

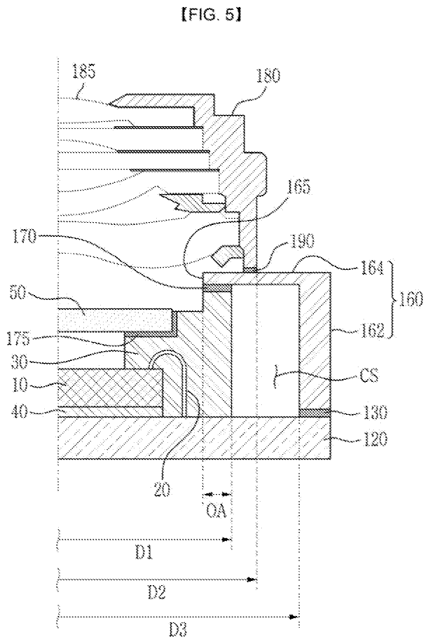

According to an example embodiment, the housing 160 may include an exterior wall 162 and a cover 164. The exterior wall 162 may be attached to the substrate 120 and may surround the image sensor chip 10. More particularly, the exterior wall 162 may be spaced apart from the encapsulant 30 surrounding the side part of the image sensor chip 10 and may surround the encapsulant 30. In an implementation, the width (D3, referring to FIG. 5) of the inner surface of the exterior wall 162 may be greater than the width (referring to D1, FIG. 5) of the encapsulant 30. The encapsulant 30 is described later.

Meanwhile, in this specification, “a width” may be defined as the length of the horizontal direction (an X-axis direction), and “a thickness” may be defined as the length of the vertical direction (a Z-axis direction).

The exterior wall 162 may be bonded to the upper surface of the substrate 120 by the second adhesive layer 130. The second adhesive layer 130 may be made of a material having an adherence, and may include, e.g., an epoxy resin.

The exterior wall 162 may extend upward from the upper surface of the substrate 120, and e.g., the exterior wall 162 may stand vertically on the upper surface of the substrate 120. That is, the exterior wall 162 may have a cylinder shape. In an implementation, as shown in FIG. 1, the exterior wall 162 may have a square cylinder shape.

The cover 164 may cover the upper part of the exterior wall 162 and may be a part forming an opening 165. The cover 164 may extend inward from the exterior wall 162 (in a direction in which the image sensor chip is positioned) to form the opening 165. In an implementation, the cover 164 may extend in a horizontal direction from the upper end of the exterior wall 162, and the opening 165 may have a square shape.

On a plane, the image sensor chip 10 may be positioned within the opening 165, and the opening 165 may have a region larger than that of the image sensor chip 10. The circumference of the opening 165 may be supported by an encapsulant 30.

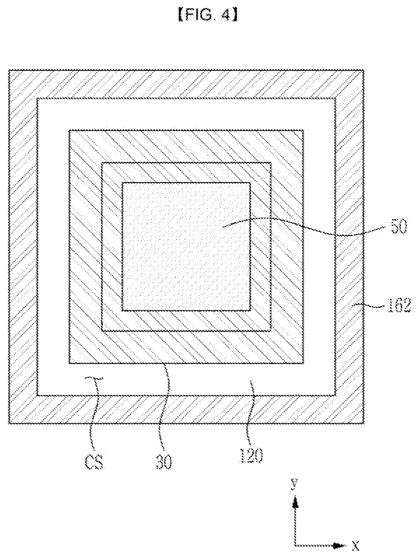

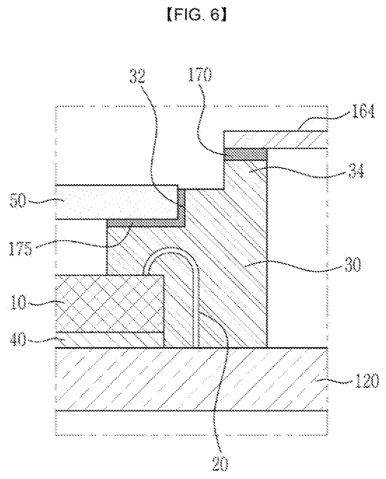

FIG. 4 is a cross-sectional view of a direction B-B of FIG. 2, and FIG. 5 is a view of a size relationship between components. FIG. 6 is an enlarged view showing a part C of FIG. 2. In FIG. 5, since the cross-sectional view of the image sensor module has a symmetrical structure with the vertical center line as a reference, only the right side is shown. The characteristics of the encapsulant 30 according to an embodiment are explained in detail with reference to FIG. 4 to FIG. 6.

The encapsulant 30 may be a part that encapsulates and protects the bonding wire 20. In addition, the encapsulant 30 may prevent the contamination of the image sensor chip 10 die to articles generated during the assembly process of the image sensor module 100.

According to an example embodiment, the encapsulant 30 may encapsulate the bonding wire 20 by surrounding the side part of the image sensor chip 10. As described above, the bonding wire 20 may connect the chip pad 12 disposed on the edge of the image sensor chip 10 and the substrate pad 122 on the substrate 120 around the image sensor chip 10. Accordingly, the encapsulant 30 may cover the side part of the image sensor chip 10, thereby encapsulating the bonding wire 20.

More specifically, the encapsulant 30 may cover the edge region of the image sensor chip 10 in which the chip pad 12 is disposed and a partial region (specifically, the circumference region of the image sensor chip 10 among the upper surfaces of the substrate) of the upper surface of the substrate 120 in which the substrate pad 122 is disposed together, thereby the bonding wire 20 may be encapsulated.

According to an example embodiment, the encapsulant 30 may define a separation space CS between the housing 160 and the encapsulant 30. That is, referring to FIG. 2 and FIG. 4, the separation space CS may be defined between the housing 160 and the encapsulant 30.

The exterior wall 162 of the housing 160 may be spaced apart from the encapsulant 30 and surround the encapsulant 30. That is, the encapsulant 30 may be accommodated in the inner space of the housing 160, but the encapsulant 30 may be positioned apart from the exterior wall 162 of the housing 160. Accordingly, the separation space CS may be defined between the housing 160 and the encapsulant 30.

By providing the separation space CS between the housing 160 and the encapsulant 30, a region covered by the encapsulant 30 on the substrate 120 may be minimized. In other words, since the encapsulant 30 may cover only the circumference region of the image sensor chip 10 among the regions of the substrate 120 surrounded by the housing 160, a stress applied to the image sensor chip 10 during the curing of the encapsulant 30 may be reduced.

The encapsulant 30 may include a molding compound, a molding underfill, an epoxy and/or a resin. According to an example embodiment, the encapsulant 30 may be Epoxy Molding Compounds (EMC). In an implementation, the encapsulant 30 may be formed by positioning a mold M corresponding to the shape of the encapsulant 30 on the substrate 120, implanting EMC in the mold, and then hardening the mold.

According to an example embodiment, the encapsulant 30 may support the housing 160. In an implementation, the encapsulant 30 may support the upper cover 164 of the housing 160.

Referring to FIG. 2 and FIG. 5, the lower surface of the cover 164 of the housing 160 may be attached on the upper surface of the encapsulant 30. The lower surface of the cover 164 may be attached to the upper surface of the encapsulant 30 through the third adhesive layer 170. Accordingly, the upper surface of the encapsulant 30 may support the lower surface of the cover 164 of the housing 160. The third adhesive layer 170 may be made of a material having an adherence and may include, e.g., an epoxy resin.

More specifically, the lower surface of the circumference of the opening 165 of the cover 164 may be supported to the upper surface of the encapsulant 30. That is, since the encapsulant 30 may function as a support structure supporting the housing 160, the strength of the rear surface of the image sensor module 100 may be increased.

According to an example embodiment, as shown in FIG. 6, the encapsulant 30 may be with a protruding portion 34 and a step part 32. The protruding portion 34 may be a portion protruded upward from the upper surface of the encapsulant 30 and may support the housing 160. According to an example embodiment, the cover 164 may be attached on the protruding portion 34 through the third adhesive layer 170. The protruding portion 34 may be formed on an outer portion of the encapsulant 30.

The step part 32 may be a downwardly concave part and may support the optical filter 50 to be described later. According to an example embodiment, the step part 32 may be formed at the upper part of the encapsulant 30, and the optical filter 50 may be seated within the step part 32. In an implementation, a fourth adhesive layer 175 may be inside the step part 32 and the optical filter 50 may be attached within the step part 32. In this way, the encapsulant 30 may function as a support structure supporting the optical filter 50. The fourth adhesive layer 175 may be made of a material having an adherence and may include, e.g., an epoxy resin.

The optical filter 50 may be a part that may pass or block light of a specific wavelength band, and may be spaced apart from the image sensor chip 10 and disposed on the image sensor chip 10. In an implementation, the optical filter 50 may include an IR filter for filtering infrared rays or near infrared rays.

According to an example embodiment, the optical filter 50 may be attached to the encapsulant 30. As described above, the optical filter 50 may be seated in the step part 32 in the encapsulant 30. That is, the encapsulant 30 may function as a support structure supporting the optical filter 50.

The optical filter 50 may maintain a predetermined interval with the lens 185 inside the lens holder 180. According to an example embodiment, a distance greater than a predetermined interval between the optical filter 50 and the lens 185, e.g., a distance of 0.4 mm or more may be maintained through the protruding portion 34 of the encapsulant 30 described above.

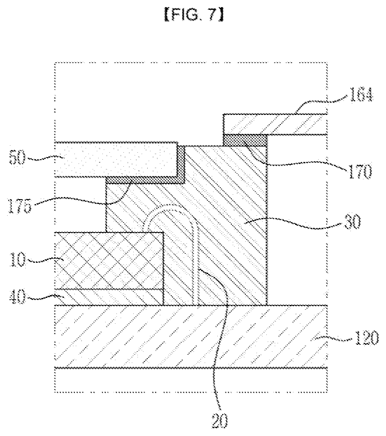

FIG. 7 is a view showing a modified form of a part C of FIG. 2. When a distance equal to or longer than a predetermined interval is sufficiently maintained between the optical filter 50 and the lens 185, the encapsulant 30 may not have a protruding portion. That is, referring to FIG. 7, the cover 164 may be attached to the upper surface of the encapsulant 30.

The lens holder 180 may be coupled to the upper part of the housing 160. According to an example embodiment, the lens holder 180 may be coupled to the cover 164 of the housing 160. The lens holder 180 may include a plurality of lenses 185 therein.

More specifically, referring to FIG. 5, the lens holder 180 may be combined with the upper surface of the cover 164 through the fifth adhesive layer 190. The fifth adhesive layer 190 may be made of a material having adherence, and may include, e.g., an epoxy resin.

The lens holder 180 may have a square cylinder shape and may be attached to the upper surface of the circumference of the opening 165 of the cover 164. According to an example embodiment, the lens holder 180 may have a width greater than or equal to the encapsulant 30. In an implementation, on a plane, the cover 164 may have a region in which the lens holder 180 and the encapsulant 30 overlap. Accordingly, the strength of the rear surface of the image sensor module 100 may be further increased.

As described above, in order for the encapsulant 30 to function as a support structure supporting the housing 160, the cover 164 of the housing 160 may have a region OA overlapping with the encapsulant 30 on a plane. In addition, the cover 164 of the housing 160 may have a region in which the lens holder 180 and the encapsulant 30 overlap.

According to an example embodiment, the width of the housing 160 may be greater than the width of the lens holder 180, and the width of the encapsulant 30 may be equal to or smaller than the width of the lens holder 180. Referring to FIG. 5, the width D3 between the inner surfaces of the facing exterior walls 162 is greater than the width D2 of the lens holder 180, and the width D1 of the encapsulant 30 may be equal to or smaller than the width D2 of the lens holder 180.

That is, while the encapsulant 30 may overlap the cover 164 to support the lower surface of the cover 164, it also may overlap the lens holder 180 attached to the upper surface of the cover 164 to support the lens holder 180 together. Accordingly, the strength of the rear surface of the image sensor module 100 may be increased.

However, when the width D1 of the encapsulant 30 is greater than the width D2 of the lens holder 180, the volume of the encapsulant 30 may increase, so the stress applied to the image sensor chip 10 may increase during the curing of the encapsulant 30. Therefore, the encapsulant 30 may support the lower surface of the cover 164 and also may support the lens holder 180 attached to the upper surface of the cover 164, thereby reducing the stress applied to the image sensor chip 10 and increasing the strength of the rear surface of the image sensor module 100. In this case, the width D1 of the encapsulant 30 may be equal to or smaller than the width D2 of the lens holder 180.

A Chip On Board (COB) in which the image sensor chip 10 may be mounted on the upper surface of the substrate 120 has been described. However, in the case of another embodiment, the same configuration may be applied to a form in which the image sensor chip 10 may be inserted into a through-hole of the substrate 120 and installed. Hereinafter, another embodiment will be described with reference to drawings.

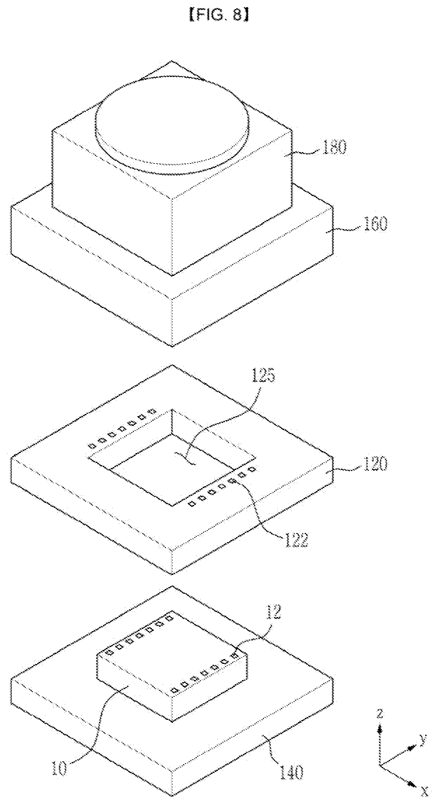

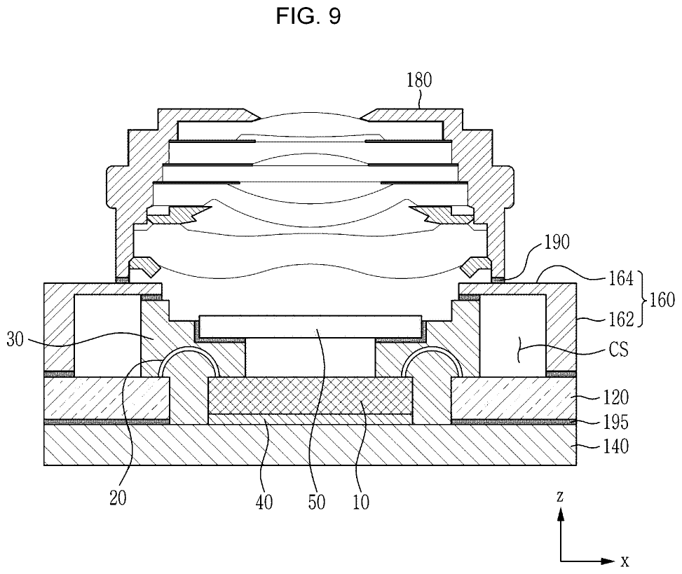

FIG. 8 is an exploded perspective view of an image sensor module according to an example embodiment, and FIG. 9 is a cross-sectional view of an image sensor module according to an example embodiment.

Referring to FIG. 8 and FIG. 9, the substrate 120 may include a stiffener 140 attached to the lower surface. The substrate 120 may have a through-hole 125, and the image sensor chip 10 may be positioned within the through-hole 125. The present embodiment may reduce the height of the image sensor module 100 and increase the effect of preventing the damage and deformation of the image sensor chip 10 compared to the above-mentioned embodiment.

In an implementation, the image sensor chip 10 may be attached to the upper surface of the stiffener 140 through the first adhesive layer 40, and the upper surface of the stiffener 140 may be attached to the lower surface of the substrate 120. At this time, the substrate 120 and the stiffener 140 may be combined so that the image sensor chip 10 may be positioned within the through-hole 125 of the substrate 120.

The substrate 120 and the stiffener 140 may be attached to each other by a sixth adhesive layer 195. The fifth adhesive layer 190 may be made of a material having an adherence, and may include, e.g., an epoxy resin.

The stiffener 140 may have a plate shape and may include a ceramic or metallic material. In an implementation, the stiffener 140 may include stainless steel (SUS) or copper (Cu) alloy. The stiffener 140 may prevent an external impact applied to the image sensor chip 10 and a warpage of the image sensor chip 10.

In the present embodiment, an encapsulant 30 may be filled in a gap between the image sensor chip 10 and the through-hole 125. That is, the encapsulant 30 may cover the circumference of the through-hole 125 of the substrate 120 and the side part of the image sensor chip 10, and also fill the gap between the image sensor chip 10 and the through-hole 125 to seal the bonding wire 20.

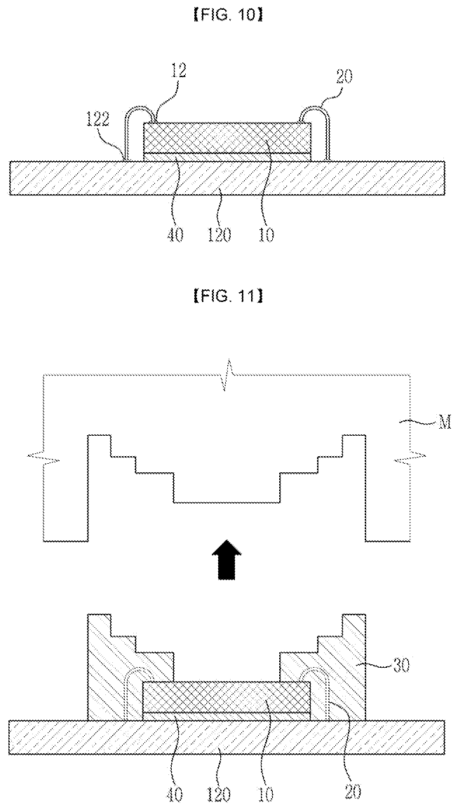

Hereinafter, a manufacturing method of the image sensor module 100 of an example embodiment will be described with reference to drawings. FIG. 10 to FIG. 12 are views showing a manufacturing method of an image sensor module according to an example embodiment. FIG. 10 to FIG. 12 describes a COB form among the above embodiments as an example.

Referring to FIG. 10, an image sensor chip 10 may be mounted on a substrate 120. The image sensor chip 10 may be attached to the upper surface of the substrate 120 through the first adhesive layer 40, and the bonding wire 20 may be connected between the chip pad 12 on the upper surface edge of the image sensor chip 10 and the substrate pad 122 on the upper surface of the substrate 120.

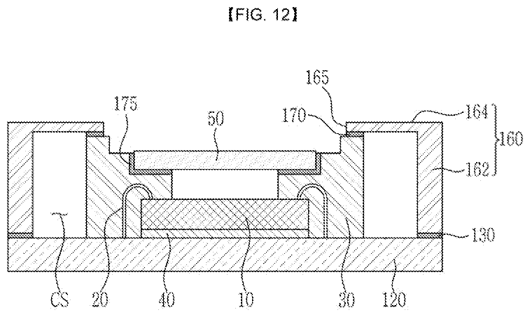

Referring to FIG. 11, the bonding wire 20 may be encapsulated by the encapsulant 30. In an implementation, the encapsulant 30 may be formed by positioning a mold M corresponding to the encapsulant 30 on the substrate 120, implanting the EMC in the mold M, and curing the EMC. After the encapsulant 30 is cured, the mold M may be removed.

The encapsulant 30 may cover only a portion of the upper surface of the substrate 120. In an implementation, only the circumference region of the image sensor chip 10 and the edge portion of the image sensor chip 10 among the upper surface of the substrate 120 may cover the encapsulant 30, thereby encapsulating the bonding wire 20.

In FIG. 6, the encapsulant 30 may be formed to include a protruding portion 34 supporting the cover 164 of the housing 160 and a step part 32 supporting the optical filter 50.

Referring to FIG. 12, an optical filter 50 may be attached to the upper part of the encapsulant 30. In an implementation, the optical filter 50 may be seated on the concave-shaped step part 32. An optical filter 50 may be attached to the step part 32 through the fourth adhesive layer 175.

The optical filter 50 may be spaced apart from the image sensor chip 10 and positioned above the image sensor chip 10. Referring to FIG. 12, the housing 160 may be attached to the upper surface of the substrate 120. The lower end of the exterior wall 162 of the housing 160 may be attached to the upper surface of the substrate 120 through the second adhesive layer 130.

The lower surface of the cover 164 of the housing 160 may be attached to the upper surface of the encapsulant 30. In an implementation, the lower surface of the circumference of the opening 165 of the cover 164 may be attached to the upper surface of the protruding portion 34 of the encapsulant 30 through the third adhesive layer 170.

The exterior wall 162 of the housing 160 may be attached to the upper surface of the substrate 120 while being spaced apart from the encapsulant 30. Accordingly, a separation space CS may be defined between the housing 160 and the encapsulant 30.

After assembling the housing 160, the lens holder 180 may be coupled to the upper part of the housing 160. In an implementation, referring to FIG. 2, the lens holder 180 may be attached to the upper surface of the circumference of the opening 165 of the cover 164 through the fifth adhesive layer 190.

By way of summation and review, in recent years, according to a rapid development of an electron industry and a request of a user, electronic devices to which the image sensors are applied are becoming more down-sized and multifunctional. Accordingly, the size of the substrate on which the image sensors are mounted has been increased for the down-size and multifunctionality of the module including the image sensor, and a research on a packaging technology for effectively mounting the image sensors on the substrate is being actively conducted.

When packaging the image sensor chip by using an epoxy material encapsulant, a stress is transmitted to the image sensor chip during the curing process of the encapsulant, resulting in cracks in the image sensor or a damage to the pixels.

In addition, in the case of the image sensor module in which a large optical system is used to implement the fine pixels, the size of the substrate is increased, and a separate support structure is required to support the optical filter in the module, so that there is a problem that the strength of the rear surface of the module is weakened.

One aspect is to provide an image sensor module capable of increasing a back strength by being packaged with an encapsulant. In addition, it is intended to provide an image sensor module that can reduce the stress applied to the chip during an encapsulant curing. According to an embodiment, the back strength of the image sensor module may be increased by packaging the image sensor chip with the encapsulant. In addition, by applying the encapsulant only to the region around the image sensor chip, the stress applied to the image sensor chip during the encapsulant hardening may be reduced.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present invention is not limited to the illustrated sizes and thicknesses.

Throughout this specification and the claims that follow, when it is described that an element is “coupled” to another element, the element may be “directly coupled” to the other element or “electrically coupled” to the other element through a third element. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, in the specification, the phrase “on a plane” means when an object portion is viewed from above, and the phrase “on a cross-section” means when a cross-section taken by vertically cutting an object portion is viewed from the side. An image sensor module of an embodiment was described with reference to drawings.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An image sensor module, comprising:
an image sensor chip configured to convert light collected from an outside into an electric signal;
a substrate on which the image sensor chip is installed;
a bonding wire electrically connecting the image sensor chip and the substrate;
an encapsulant for encapsulating the bonding wire by surrounding the side part of the image sensor chip; and
a housing having a lower part spaced apart from the encapsulant and bonded on the substrate, and an upper part having an opening through which an external light is incident to the image sensor chip and supported by the encapsulant.

2. The image sensor module as claimed in claim 1, wherein a separation space is defined between the housing and the encapsulant.

3. The image sensor module as claimed in claim 1, wherein the housing includes:
an exterior wall bonded on the substrate, spaced apart from the encapsulant and surrounding the encapsulant, and
a cover that extends inward from the exterior wall to form the opening and the circumference of the opening is supported by the encapsulant.

4. The image sensor module as claimed in claim 3, wherein the lower surface of the opening circumference of the cover is supported to the upper surface of the encapsulant.

5. The image sensor module as claimed in claim 3, further comprising a lens holder having a plurality of lenses inside and coupled to the cover.

6. The image sensor module as claimed in claim 3, wherein:
the lens holder is attached to the upper surface of the opening circumference of the cover, and
on a plane, the cover has a region where the lens holder and the encapsulant overlap.

7. The image sensor module as claimed in claim 3, wherein:
the encapsulant includes a protruding portion protruded upward; and
the cover is attached over the protruding portion.

8. The image sensor module as claimed in claim 1, further comprising an optical filter positioned on the image sensor chip and attached to the encapsulant.

9. The image sensor module as claimed in claim 8, wherein a concave step part is on the upper part of the encapsulant, and the optical filter is seated on the step part.

10. The image sensor module as claimed in claim 1, wherein:
the image sensor chip is attached to the upper surface of the substrate, and
the encapsulant covers the circumference region of the image sensor chip of the substrate upper surface.

11. The image sensor module as claimed in claim 1, further comprising:
a stiffener attached to the substrate lower surface,
the substrate having a through-hole, and
the image sensor chip attached to the upper surface of the stiffener and positioned within the through-hole.

12. The image sensor module as claimed in claim 11, wherein the encapsulant is filled in a gap between the image sensor chip and the through-hole.

13. The image sensor module as claimed in claim 11, wherein the stiffener includes a ceramic or a metallic material.

14. An image sensor module, comprising:
an image sensor chip that converts light collected from an outside into an electric signal;
a substrate on which the image sensor chip is installed;
a bonding wire connecting a chip pad on the upper surface edge of the image sensor chip and a substrate pad on the upper surface of the substrate;
a housing coupled to the substrate, surrounding the image sensor chip, and having an opening through which an external light is incident to the image sensor chip;
an optical filter positioned on the image sensor chip and spaced apart from the image sensor chip; and
an encapsulant that encloses the side part of the image sensor chip to encapsulate the bonding wire, supports the upper portion of the housing while defining a separation space with the housing, and supports the optical filter.

15. The image sensor module as claimed in claim 14, further comprising a lens holder with a plurality of lenses therein and coupled to the upper portion of the housing.

16. The image sensor module as claimed in claim 15, wherein:
the width of the housing is greater than the width of the lens holder, and
the width of the encapsulant is less than or equal to the width of the lens holder.

17. The image sensor module as claimed in claim 14, further comprising:
a stiffener attached to the substrate lower surface;
the substrate having the through-hole, and
the image sensor chip attached to the upper surface of the stiffener and positioned within the through-hole.

18. The image sensor module as claimed in claim 17, wherein the encapsulant is filled in the gap between the image sensor chip and the through-hole.

19. The image sensor module as claimed in claim 14, wherein the encapsulant includes:
a protruding portion protruded to support the upper part of the housing, and
a concave step part to support the optical filter.

20. An image sensor module, comprising:
an image sensor chip that converts light collected from an outside into an electric signal;
a substrate on which the image sensor chip is installed;
a bonding wire electrically connecting the image sensor chip and the substrate;
an encapsulant that encloses a side part of the image sensor chip and encapsulates the bonding wire while covering some regions of the upper surface of the substrate;
an optical filter positioned on the image sensor chip spaced apart from the image sensor chip and supported on the encapsulant;
a housing including an exterior wall that is bonded to the substrate, spaced apart from the encapsulant and that surrounds the encapsulant, and a cover that is spaced apart from the substrate, extends inward from the exterior wall, has an opening through which an external light is incident to the image sensor chip, and is supported to the upper surface of the encapsulant; and
a lens holder having a plurality of lenses, combined on the cover, and having a width greater than or equal to that of the encapsulant.
